(19) United States
(12) Patent Application Publication
(10) Pub. No.: US 2026/0290421 A1
(43) Pub. Date: Sep. 24, 2026

(54) MEMORY DEVICES, OPERATING METHODS THEREOF AND MEMORY SYSTEMS

(71) Applicant: Yangtze Memory Technologies Holding Co., Ltd., Wuhan (CN)

(72) Inventors: Zhipeng Dong, Wuhan (CN); Zhuangzhuang Lin, Wuhan (CN); Ke Liang, Wuhan (CN); Lei Liu, Wuhan (CN); ZhiLiang Xia, Wuhan (CN); Chunyuan Hou, Wuhan (CN)

(21) Appl. No.: 19/342,175

(22) Filed: Sep. 26, 2025

(30) Foreign Application Priority Data
Mar. 18, 2025 (CN) 202510323306.9

(51) Int. Cl. G11C 11/22

(52) U.S. Cl. CPC G11C 11/2277; G11C 11/2255; G11C 11/2273; G11C 11/2275

(57) ABSTRACT

The disclosure includes memory devices, operating methods thereof and memory systems. An example memory device includes: a memory array including a plurality of memory blocks, a memory block includes a plurality of ferroelectric memory cells; a plurality of word lines coupled with the memory array; and a peripheral circuit coupled with the memory array and configured to: perform an erase operation on a target memory block of the plurality of memory blocks, so that a plurality of ferroelectric memory cells in the target memory block are in an erased state; apply a first verify voltage on a selected word line coupled to the target memory block to perform a first verify operation; apply a first program voltage on the selected word line to perform a first program operation; and apply a second verify voltage on the selected word line to perform a second verify operation.

### CROSS-REFERENCE TO RELATED APPLICATIONS

This application claims priority to and the benefit of Chinese Patent Application 202510323306.9, filed on Mar. 18, 2025, which is hereby incorporated by reference in its entirety.

### TECHNICAL FIELD

The present disclosure relates to the field of semiconductor technology, and more particularly to, but is not limited to, memory devices, operating methods thereof, and memory systems.

### BACKGROUND

Memory devices are storage apparatus used in modern information technology to store information. As a typical non-volatile semiconductor memory, NAND (Not-And) memory has gradually become a mainstream product in the memory market due to its high memory density, controllable production cost and proper erasing speed. However, with the increasing demand for memory device, there is still significant room for improvement in memory devices and their systems.

### BRIEF DESCRIPTION OF THE DRAWINGS

FIG. 1 is a schematic diagram of an example system with a memory system provided by an example of the present disclosure;

FIG. 2 is a schematic diagram of an example memory card provided by an example of the present disclosure;

FIG. 3 is a schematic diagram of an example solid state drive provided by an example of the present disclosure;

FIG. 4 is a schematic diagram of an example memory device including a peripheral circuit provided by an example of the present disclosure;

FIG. 5 is a schematic cross-sectional view of a peripheral circuit provided by an example of the present disclosure;

FIG. 6 is a schematic cross-sectional view of an example memory array including memory strings provided by an example of the present disclosure;

FIG. 7 is a schematic diagram of a polarization direction of a ferroelectric layer in a ferroelectric memory cell provided by an example of the present disclosure;

FIG. 8 is a schematic diagram of memory states of a ferroelectric memory cell in a TLC mode provided by an example of the present disclosure;

FIG. 9 is a schematic diagram of another system including a host and a memory system provided by an example of the present disclosure;

FIG. 10 is a first schematic diagram of threshold voltage distribution of a plurality of ferroelectric memory cells in a target memory block after a first program operation is performed, provided by an example of the present disclosure;

FIG. 11 is a second schematic diagram of threshold voltage distribution of a plurality of ferroelectric memory cells in a target memory block after a first program operation is performed, provided by an example of the present disclosure;

FIG. 12 is a schematic flowchart of a method of operating a memory device provided by an example of the present disclosure.

### DETAILED DESCRIPTION

Example implementations of the present disclosure will be described in more detail below with reference to the accompanying drawings. Although examples of the present disclosure are shown in the drawings, it should be understood that the present disclosure may be implemented in various forms and should not be limited by the examples set forth herein. Rather, these examples are provided so that the present disclosure can be more thoroughly understood, and the scope of the disclosure can be completely conveyed to those skilled in the art.

In the following description, numerous specific details are given in order to provide a more thorough understanding of the present disclosure. However, it will be apparent to those skilled in the art that the present disclosure may be practiced without one or more of these details. In other examples, to avoid confusion with the present disclosure, some technical features known in the art are not described; that is, not all the features of actual examples not described herein, and well-known functions and structures are not described in detail.

In the drawings, same reference numerals refer to same elements throughout.

It should be understood that spatial relationship terms such as “under,” “below,” “lower,” “beneath,” “above,” “upper” and the like may be used herein for ease of description to describe one element or feature's relationship to other elements or features shown in the figures. It should be appreciated that the spatial relationship terms are intended to include different orientations of a device in use and operation in addition to the orientations shown in the figures. For example, if the devices in the figures are flipped, then an element or feature described as being “under” or “below” or “beneath” other elements will be oriented “on” other elements or features. Thus, the example terms “under” and “below” can include both upper and lower orientations. The device may additionally be oriented (rotated 90 degrees or other orientation) and the spatial description terms used herein are interpreted accordingly.

The terms used herein are only for the purpose of describing examples and not as a limitation of the present disclosure. As used herein, the singular forms “a,” “an,” and “the” are also intended to include the plural forms unless the context clearly indicates otherwise. It should also be understood that the terms “comprise” and/or “include,” when used in this specification, determine the presence of stated features, integers, steps, operations, elements and/or components, but do not preclude the presence or addition of one or more other features, integers, steps, operations, elements, components and/or groups. As used herein, the term “and/or” includes any and all combinations of related listed items.

Although NAND-type memories perform well in terms of memory density, production cost, and erase speed, they still have limitations in some application scenarios. For example, the read/write speed and endurance of the NAND-type memories are relatively low, and the erase operation of the NAND-type memories requires large energy consumption and time, which limits their application in scenarios with high requirements for real-time performance and high reliability. Based on research in the industry, by adding a ferroelectric material to a three-dimensional NAND type memory, reliability of the memory device can be improved, and the memory device is further scaled down. The ferroelectric layer may be disposed between the gate base layer and the channel layer to form a ferroelectric transistor, thereby forming a three-dimensional NAND-type ferroelectric memory (3D FeNAND). The novel memory not only has the advantages of high density and low cost, but also integrates the characteristics of high speed, low power consumption and high endurance of a ferroelectric random access memory (FeRAM), therefore can provide higher performance and wider application scenarios, and can also meet higher requirements of future storage technologies on speed, power consumption and reliability.

A three-dimensional NAND-type ferroelectric memory device and a memory system including the three-dimensional NAND-type ferroelectric memory device are in some examples described below with reference to the accompanying drawings.

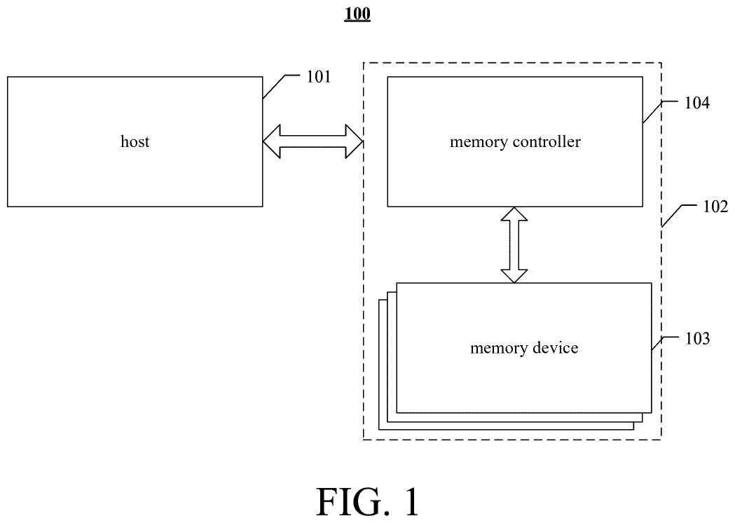

FIG. 1 is a schematic diagram of an example system with a memory system provided by an example of the present disclosure. In the examples of the present disclosure, the system may be a mobile phone, a desktop computer, a laptop computer, a tablet computer, a vehicle computer, a game console, a printer, a positioning device, a wearable electronic device, an intelligent sensor, a virtual reality (VR) device, an augmented reality (AR) device, or any other suitable electronic device having a memory therein. As shown in FIG. 1, system 100 may include a host 101 and a memory system 102 which may include one or more memory devices 103 and a memory controller 104. The host 101 may include a processor of an electronic device, for example, a central processing unit (CPU), or a system on a chip (SoC), for example, an application processor (AP). The host 101 may be configured to send data to or receive data from the memory system 102.

In some implementations, the memory controller 104 is coupled to the memory device 103 and the host 101 and is configured to control the memory device 103. The memory controller 104 may manage data stored in the memory device 103 and communicate with the host 101. In some examples, the memory controller 104 is designed for operation in a low duty cycle environment, such as in a secure digital card, a Compact Flash Card (CFC), a Universal Serial BUS (USB) flash drive, or other medium for use in electronic devices such as personal calculators, digital cameras, mobile phones, etc. In some other implementations, the memory controller 104 is designed for operation in a high duty cycle environment, such as a solid state drive or an embedded Multi-Media Card (eMMC).

In some examples, the memory controller 104 and the one or more memory devices 103 may be integrated into various types of storage apparatus, that is, the memory system 102 may be implemented and packaged into different types of terminal electronic products.

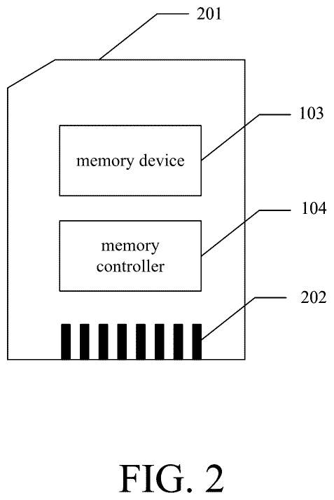

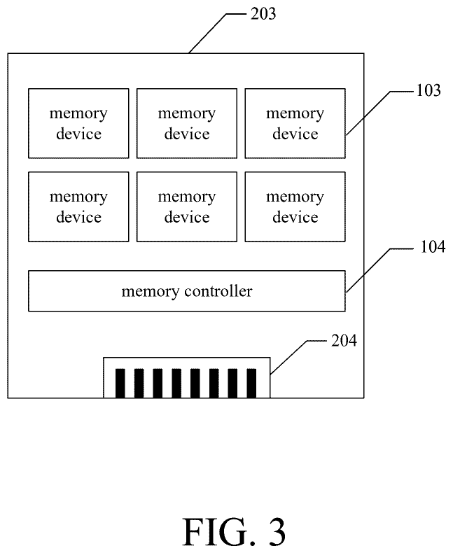

In one example as shown in FIG. 2, the memory controller 104 and the single memory device 103 may be integrated into the memory card 201. The memory card 201 may be one of a compact flash memory card, a smart media card (SMC), a memory stick (MS), a multi-media card (MMC) (such as an RS-MMC, an MMCmicro, an eMMC, or the like), a secure digital card, (such as a MiniSD card, a Micro SD card, an SDHC card, or the like), or a universal flash memory card. The memory card 201 may also include a memory card connector 202 that couples the memory card 201 with a host-side device (e.g., host 101 in FIG. 1). In another example as shown in FIG. 3, the memory controller 104 and the plurality of memory devices 103 may be integrated into a solid state drive (solid state drive, SSD) 203. SSD203 may also include an SSD connector 204 that couples SSD203 with a host-side device (e.g., host 101 in FIG. 1). In some implementations, the storage capacity and/or operating speed of SSD203 is greater than the storage capacity and/or operating speed of memory card 201.

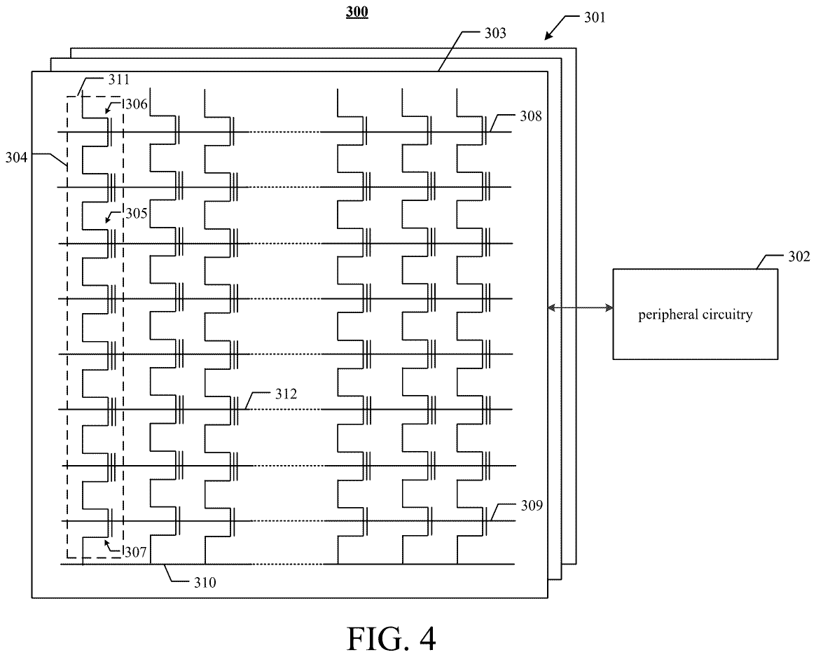

FIG. 4 is a schematic circuit diagram of an example memory device 300 including a peripheral circuit provided by an example of the present disclosure. Memory device 300 may be an example of memory device 103 in FIG. 1. The memory device 300 may include a memory array 301 and peripheral circuit 302 coupled to the memory array 301.

In some examples, the peripheral circuit 302 may include any suitable analog, digital, and mixed signal circuit for achieve operations on the memory array 301 by applying voltage and/or current signals to and sensing voltage and/or current signals from each target memory cell through bit lines 311, word lines 312, common source lines 310, bottom select lines 309, and top select lines 308. The peripheral circuit 302 may include various types of peripheral circuit formed using metal-oxide-semiconductor technology.

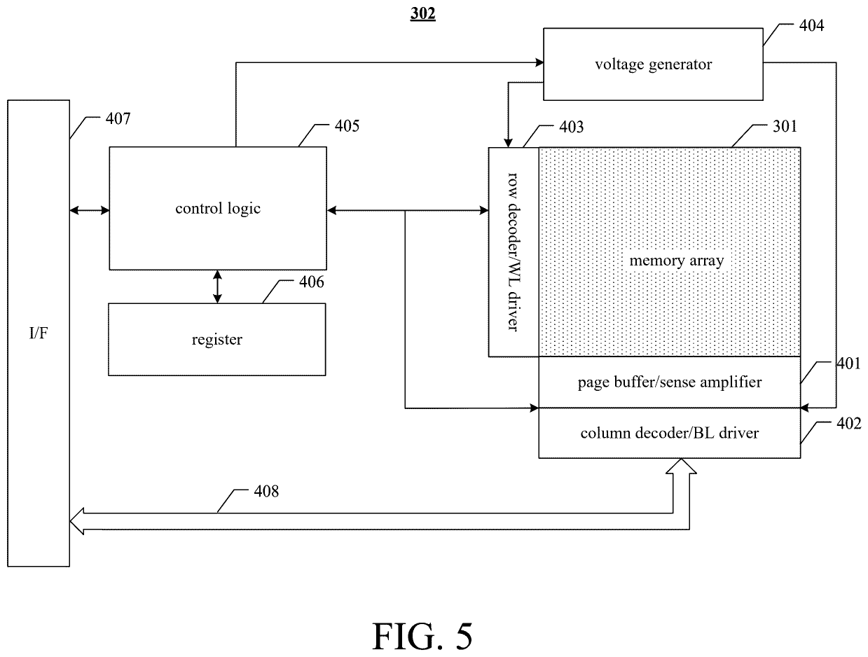

FIG. 5 illustrates some example peripheral circuit 302 including a page buffer/sense amplifier 401, a column decoder/bit line driver 402, a row decoder/word line driver 403, a voltage generator 404, control logic 405, registers 406, flash interface I/F407, and a data bus 408. It should be understood that in some examples, additional peripheral circuit not shown in FIG. 5 may also be included.

The page buffer/sense amplifier 401 may be configured to read data from and program (write) data to the memory array 301 according to control signals from the control logic 405. In one example, the page buffer/sense amplifier 401 may store a page of program data (write data) to be programmed to the memory array 301. In another example, the page buffer/sense amplifier 401 may perform a program verify operation to ensure that data has been correctly programmed into memory cells coupled to the selected word line. In yet another example, the page buffer/sense amplifier 401 may also sense a low power signal from a bit line representing a data bit stored in a memory cell and amplify a small voltage swing to an identifiable logic level in a read operation. The column decoder/bit line driver 402 may be configured to be controlled by the control logic 405 and to select one or more memory strings by applying a bit line voltage generated from voltage generator 404.

The row decoder/word line driver 403 may be configured to be controlled by control logic 405 and select/deselect memory blocks of memory array 301 and select/deselect word lines of memory blocks. The row decoder/word line driver 403 may also be configured to drive word lines using word line voltages generated from the voltage generator 404. In some implementations, the row decoder/word line driver 403 may also select/deselect and drive the bottom select line and the top select line. As described in detail below, the row decoder/word line driver 403 is configured to perform a program operation on a memory cell coupled to the selected word line(s). The voltage generator 404 may be configured to be controlled by the control logic 405 and generate a word line voltage (e.g., a read voltage, a program voltage, a pass voltage, a local voltage, a verify voltage, etc.), a bit line voltage, and a source line voltage to be supplied to the memory array 301.

Control logic 405 may be coupled to each peripheral circuit described above and configured to control operation of each peripheral circuit. Registers 406 may be coupled to control logic 405 and include status registers, command registers, and address registers for storing status information, command opcodes (OP codes), and command addresses for controlling operation of each peripheral circuit. Flash interface 407 may be coupled to control logic 405 and act as a control buffer to buffer and relay control commands received from a host-side device (not shown) to control logic 405 and to buffer and relay status information received from control logic 405 to a memory controller. Flash interface 407 may also be coupled to column decoder/bit line driver 402 via data bus 408 and act as a data I/O interface and data buffer to buffer and relay data to or from memory array 301.

In some examples, the memory array 301 includes a plurality of memory blocks 303, each memory block 303 includes a plurality of memory strings 304, each memory string 304 includes a plurality of memory cells 305 which are NAND ferroelectric memory cells, in other words, the memory cells 305 are provided in the form of an array of memory strings 304 extending vertically above a substrate (not shown). In some implementations, each memory string 304 includes a plurality of memory cells 305 coupled in series and stacked vertically.

Referring back to FIG. 4, as shown in FIG. 4, each memory string 304 may include a bottom select transistor (BST) 307 at its source end and a top select transistor (TST) 306 at its drain end. The bottom select transistor 307 and the top select transistor 306 may be configured to activate a selected memory string 304 during read and program operations. In some implementations, the sources of the memory strings 304 in the same memory block 303 may be coupled through a common source line (CSL) 310. In other words, all the memory strings 304 in the same memory block 303 have a common source (ACS). According to some implementations, the top select transistor 306 of each memory string 304 is coupled to a respective bit line (BL) 311 from which data may be read or written via an output bus (not shown). In some implementations, each memory string 304 is configured to be selected or deselected by applying a select voltage (e.g., a voltage above a threshold voltage of the top select transistor 306) or a deselect voltage (e.g., 0V) to a top select gate (TSG) of the respective top select transistor 306 through one or more top select lines (TSL) 308 and/or by applying a select voltage (e.g., a voltage above a threshold voltage of the bottom select transistor 307) or a deselect voltage (e.g., 0V) to a bottom select gate (BSG) of the respective bottom select transistor 307 through one or more bottom select lines (BSL) 309.

As shown in FIG. 4, the memory string 304 may be organized into a plurality of memory blocks 303, each of which may have a common source line 310. In some examples, each memory block 303 is a basic unit of data for an erase operation, i.e., all memory cells 305 on the same memory block 303 are erased simultaneously. To erase memory cells 305 in a selected memory block, a common source line 310 coupled to the selected memory block and unselected memory blocks on the same plane as the selected memory block may be biased with an erase voltage. It should be appreciated that in some examples, the erase operation may be performed at a half memory block level, at a quarter memory block level, or at a level having any suitable number of memory blocks or any suitable fraction of a memory block. The memory cells 305 of adjacent memory strings 304 may be coupled by a word line 312 that selects which row of memory cells 305 is affected by a read or program operation.

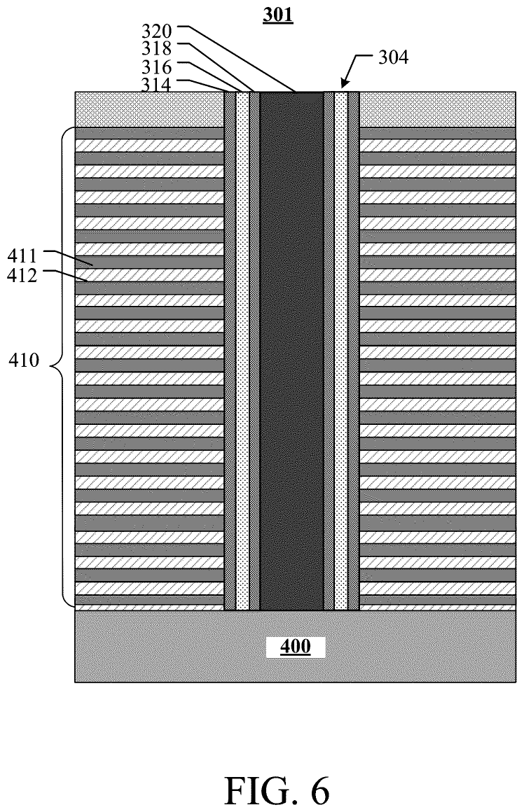

FIG. 6 is a schematic cross-sectional view of an example memory array including memory strings provided by an example of the present disclosure. As shown in FIG. 6, the memory array 301 may include a stacked structure 410 that includes a plurality of gate layers 411 and a plurality of insulating layers 412 alternately stacked in sequence, and a channel structure vertically penetrating the gate layers 411 and the insulating layers 412, wherein the channel structure is coupled to each gate layer to form a memory cell, and the channel structure is coupled to the plurality of gate layers in the stacked structure 410 to form a memory string 304. The gate layers 411 and the insulating layers 412 may be alternately stacked, and two adjacent gate layers 411 are separated by one insulating layer 412.

A composition material of the gate layer 411 may include a conductive material. The conductive material includes, but is not limited to, tungsten (W), cobalt (Co), copper (Cu), aluminum (Al), polysilicon, doped silicon, silicide, or any combination thereof. In some implementations, each gate layer 411 includes a metal layer, e.g., a tungsten layer. In some implementations, each gate layer 411 includes a doped polysilicon layer. Each gate layer 411 may include a control gate surrounding a memory cell. The gate layer 411 at the top of the stacked structure 410 may extend laterally as an upper select gate line, the gate layer 411 at the bottom of the stacked structure 410 may extend laterally as a lower select gate line, and the gate layer 411 extending laterally between the upper select gate line and the lower select gate line may serve as a word line layer.

In some examples, the stacked structure 410 may be disposed on a substrate 400. The substrate 400 may include silicon (e.g., monocrystalline silicon), silicon germanium (SiGe), gallium arsenide (GaAs), germanium (Ge), silicon on insulator (SOI), germanium on insulator (GOI), or any other suitable material.

In some examples, the memory string 304 includes a channel structure extending vertically through the stacked structure 410. In some implementations, the channel structure includes a semiconductor channel layer 320, an interface layer 318, a storage layer 316, and a barrier layer 314. The channel structure may have a cylinder shape (e.g., a pillar shape), and according to some examples, the semiconductor channel layer 320, the interface layer 318, the storage layer 316, and the barrier layer 314 are arranged radially from a center of the pillar toward an outer surface of the pillar.

In some implementations, the semiconductor channel layer 320 includes silicon, e.g., polysilicon. The interface layer 318 may include silicon oxide, silicon oxynitride, or any combination thereof. The storage layer 316 includes a ferroelectric layer, a material of the ferroelectric layer includes, but is not limited to, a Hf_{0.5}Zr_{0.5}O₂ material or a doped hafnium oxide material, and a doping element includes Zr, Y, Al, Gd, and Si. The barrier layer 314 may include silicon oxide, silicon oxynitride, a high dielectric constant (high-k) dielectric, or any combination thereof. Here, the barrier layer 314 is located between the gate layer 411 and the storage layer 316, and can block the interaction between the ferroelectric layer of the storage layer 316 and the gate layer 411, thereby improving the device performance.

In other examples, the channel structure may further include an oxide insulating layer, a semiconductor channel layer, and a storage layer sequentially disposed from inside to outside, wherein a material of the storage layer includes, but is not limited to, a Hf_{0.5}Zr_{0.5}O₂ material or a doped hafnium oxide material.

As shown in FIG. 6, the gate layer 411, the barrier layer 314, the storage layer 316, the interface layer 318, and the semiconductor channel layer 320 together form a ferroelectric transistor, that is, form a memory cell. It can be understood that the memory cell includes a gate layer 411, a portion of the barrier layer 314 corresponding to the gate layer 411, a portion of the storage layer 316, a portion of the interface layer 318, and a portion of the semiconductor channel layer 320. The information stored by the memory cell depends on the polarization direction of the ferroelectric layer in the storage layer 316.

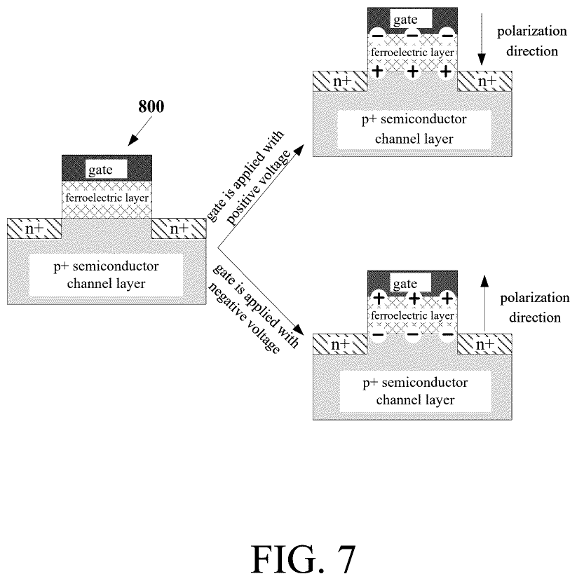

FIG. 7 is an example schematic diagram of a polarization direction of a ferroelectric layer in a ferroelectric memory cell provided by an example of the present disclosure. As shown in FIG. 7, the ferroelectric memory cell (i.e., ferroelectric transistor) 800 may include: a source and a drain disposed in a semiconductor channel layer; a ferroelectric layer disposed on the semiconductor channel layer; and a gate disposed on the ferroelectric layer. The semiconductor channel layer may be p-type (p+), the semiconductor channel layer is doped to form a source and a drain, the source and the drain may be n-type (n+), and positions of the source and the drain may be interchanged; and the gate may include, for example, a metal gate. Different voltages are applied to the gate of the ferroelectric transistor, the polarization direction of the ferroelectric layer is changed, and then the threshold voltage of the memory cell is rapidly switched to realize storage of “0” or “1”. When an erase operation is being performed, a negative voltage is applied to the gate of the ferroelectric transistor, positive charges are induced on the channel when the polarization direction of the ferroelectric layer is upward, and the threshold voltage of the ferroelectric transistor is relatively high. When a program operation is being performed, a positive voltage is applied to the gate layer of the ferroelectric transistor, negative charges are induced on the channel when the polarization direction of the ferroelectric layer is downward, and the threshold voltage of the ferroelectric transistor is relatively low. In other words, after an erase operation is performed, the threshold voltage of the ferroelectric transistor increases. After a program operation is performed, the threshold voltage of the ferroelectric transistor decreases.

In some implementations, the ferroelectric layer may not only implement the storage of “0” or “1” through different polarization directions, but also implement multi-bit storage through different polarization degrees, for example, the polarization intensity of the ferroelectric layer is changed by adjusting the magnitude of the applied voltage, so that different information is stored in different polarization states to implement multi-bit storage. For example, each memory cell is a Single Level Cell (SLC) having two possible memory states and thus can store one bit of data. Each memory cell is a multi-level cell capable of storing more than a single bit of data in four or more memory states, for example, a multi-level cell (MLC) storing two bits per memory cell, a triple level cell (TLC) storing three bits per memory cell, or a quad-level cell (QLC) storing four bits per memory cell.

Different memory cells have different numbers of memory states, for example, a SLC type memory cell has 2 memory states, wherein the 2 memory states include a programmed state and an erased state. For another example, an MLC type memory cell has 4 memory states, wherein the 4 memory states include one erased state and three programmed states. For another example, a TLC type memory cell has 8 memory states, wherein the 8 memory states include one erased state and seven programmed states. In some implementations, a QLC type memory cell has 16 memory states, wherein the 16 memory states include one erased state and fifteen programmed states.

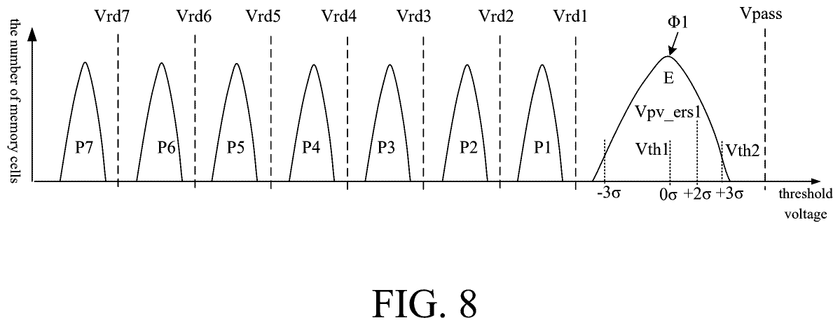

In some examples, as shown in FIG. 8, FIG. 8 is a schematic diagram of memory states of a ferroelectric memory cell in a TLC mode provided by an example of the present disclosure; wherein in the TLC mode, the ferroelectric memory cell has a capability of storing 3 bits and has 8 memory states including 1 erased states (for example, E) and 7 programmed states (for example, a first programmed state P1, a second programmed state P2, a third programmed state P3, a fourth programmed state P4, a fifth programmed state P5, a sixth programmed state P6, and a seventh programmed state P7), and each memory state may correspond to a specific range of threshold voltages. The threshold voltage of the memory cell in the erased state (for example, E) is greater than the threshold voltage of the memory cell in a programmed state, as shown in FIG. 8, the threshold voltage of the memory cell in the erased state (for example, E) is greater than the threshold voltage of the memory cell in a programmed state (for example, P1, P2, P3, P4, P5, P6, P7). In a process of performing a read operation, data of different memory states may be read by applying different read voltages (e.g., Vrd1, Vrd2, Vrd3, Vrd4, Vrd5, Vrd6, Vrd 7) to the selected word line to which the target memory cell is coupled.

However, as shown in FIG. 8, the threshold voltage corresponding to the erased state (E) is widely distributed, so that when a read operation is performed on a target memory cell in the plurality of ferroelectric memory cells, the pass voltage Vpass applied on the unselected word lines is greater than the maximum threshold voltage of all the ferroelectric memory cells, resulting in read disturbance.

Based on one or more of the above problems, the examples of the present disclosure provide another memory system, a memory device and an operating method thereof to reduce the wide distribution of the threshold voltages corresponding to the erased state, thereby reducing the pass voltage Vpass to reduce the read disturbance.

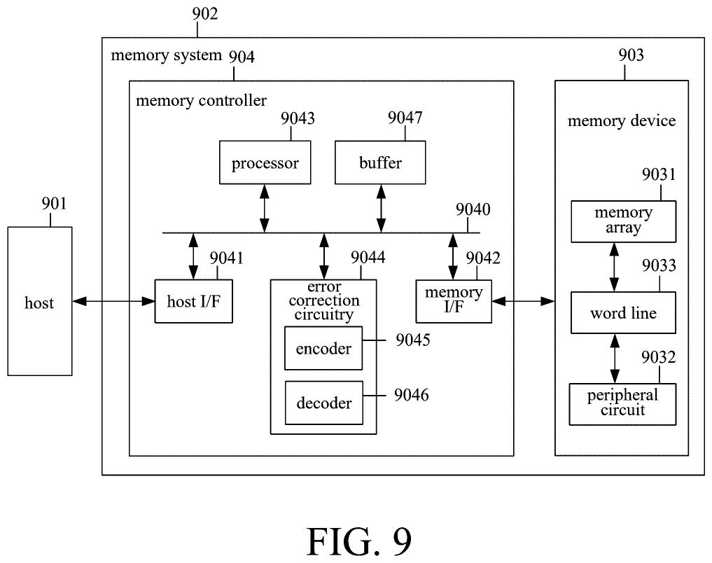

FIG. 9 is a schematic diagram of another system including a host and a memory system provided by an example of the present disclosure, as shown in FIG. 9, the memory system 902 is connected to the host 901, wherein the memory system 902 may include a memory controller 904 and a memory device 903, the memory controller 904 is configured to control the memory device 903 to perform operations such as read, write and erase, and the memory controller 904 and the memory device 903 may also be coupled in any suitable manner. The memory controller 904 may include a host interface (I/F) 9041, a memory interface (I/F) 9042, a processor 9043, error correction circuit 9044, a buffer 9047, and a bus 9040. The host interface 9041 is a connection interface connecting the host 901 and the memory controller 904, and the host interface 9041 allows the host 901 to communicate with the memory controller 904 according to a specific protocol, send read and write requests, and perform other operations. The memory interface 9042 is a connection interface between the memory controller 904 and the memory device 903 and the memory interface is configured to implement data transmission between the memory controller 904 and the memory device 903. The processor 9043 is configured to control the memory system 902 as a whole.

In some examples, the processor 9043 may include one or more units having logical operation capability, for example, a central processing unit (CPU) and/or a microcontroller unit (MCU) etc.

In some examples, the buffer 9047 is configured to buffer data, and may be a volatile memory device with a relatively fast read/write speed, such as a static random-access memory (SRAM) and/or a dynamic random-access memory (DRAM).

In some examples, the error correction circuit 9044 may be configured to encode and decode the data in a memory system using a error correcting code technique. In some examples, the error correction circuit 9044 may include an encoder 9045 and a decoder 9046, wherein the encoder 9045 may be configured to encode data to be written to the memory device in a write operation; and the decoder 9046 may be configured to decode a codeword to be decoded in read data in a read operation.

The memory device 903 may include a memory array 9031, a peripheral circuit 9032, and a plurality of word lines 9033. Here, the plurality of word lines 9033 may be coupled to the memory array 9031 in any suitable manner, and the memory array 9031 may be coupled to the peripheral circuit 9032 in any suitable manner. The memory array 9031 includes a plurality of memory blocks, each memory block may include a plurality of sub-memory blocks, and each sub-memory block may include a plurality of ferroelectric memory cells. Each memory block may be coupled to a plurality of word lines respectively connected to ferroelectric memory cells at different levels in the memory block. The peripheral circuit, the memory block, the sub-memory block, and the ferroelectric memory cell described herein are the same as the peripheral circuit, the memory block, the sub-memory block, and the ferroelectric memory cell described in the foregoing examples, and have been described above, and details are not described herein again.

In some examples, the peripheral circuit is configured to: perform an erase operation on a target memory block of a plurality of memory blocks in the memory array so that a plurality of ferroelectric memory cells in the target memory block are in an erased state; apply a first verify voltage on a selected word line coupled to the target memory block to perform a first verify operation; apply a first program voltage on the selected word line to perform a first program operation; and apply a second verify voltage on the selected word line to perform a second verify operation, wherein the second verify voltage is the same as the first verify voltage.

Here, the target memory block may be any one of the plurality of memory blocks of the memory array, and the selected word line may be any one of a plurality of word lines coupled to the target memory block. Thus, the first verify operation, the first program operation, and the second verify operation may be sequentially performed on the target memory block after the erase operation, and the first verify voltage and the second verify voltage are made to be the same, so that the threshold voltage distribution of the plurality of ferroelectric memory cells in the target memory block after the erase operation is performed is determined through the first verify operation, and the threshold voltage distribution of the plurality of ferroelectric memory cells in the target memory block after the first program operation is performed is determined through the second verify operation. In this case, a narrower threshold voltage distribution of the plurality of ferroelectric memory cells in the target memory block may be obtained by applying a program operation, which facilitates the reducing of the pass voltage applied on unselected word lines in a read operation, further improving a problem caused by read disturbance, and improving performance and reliability of the memory device and a system thereof.

In some examples, in the process of performing an erase operation, an incremental step pulse erase (ISPE) method may be used to erase the target memory block, that is, a start pulse and an ISPE step of the erase operation are fixed, voltages of erase pulses are gradually increased according to one ISPE step, and an erase verify operation is performed after each erase pulse, to determine, through the erase verify operation, whether the plurality of ferroelectric memory cells in the target memory block are in an erased state.

In some examples, in the process of performing an erase operation, whether the erase verify operation passes may be determined by obtaining the sensing current on the selected word line, and based on the magnitude of the sensing current. In some examples, when the sensing current is less than a preset value, the erase verify operation passes, and the preset value is, for example, 30 nanoamps (nA).

It should be noted that, one erase cycle includes one erase operation and one erase verify operation; in the process of executing one erase cycle, when some memory cells fail to pass the erase verification, the next erase cycle may continue to be performed; and in the process of executing the next erase cycle, the erase voltage may be gradually increased (for example, increasing ΔV) by one ISPE step, and then the erase operation and the erase verify operation are performed again, so that the erase voltage are increased by incremental step until all memory cells pass the verification. Here, after one or more erase cycle operations are performed, the plurality of ferroelectric memory cells in the target memory block are all in an erased state.

Here, after an erase cycle is performed, a first verify voltage is applied on a selected word line coupled to the target memory block to perform a first verify operation.

In some examples, the peripheral circuit is further configured to: determine, based on the first verify operation, a threshold voltage distribution of the plurality of ferroelectric memory cells in the target memory block after an erase operation is performed and before the first program operation is performed, that is, determine the threshold voltage distribution of the plurality of ferroelectric memory cells in the target memory block in an erased state. In some examples, based on the first verify operation, the number of ferroelectric memory cells of which threshold voltages are greater than the first verify voltage in the plurality of ferroelectric memory cells in the target memory block may be determined.

In some examples, the threshold voltages of the plurality of ferroelectric memory cells which are in the erased state in the target memory block are in a Gaussian normal distribution; and the peripheral circuit is further configured to: determine, in combination with a 3-sigma (3 σ) criterion, that a threshold voltage located at 0 σ in the Gaussian normal distribution is a first threshold voltage, and a threshold voltage located at +3 σ is a second threshold voltage; and the first threshold voltage is less than or equal to a first verify voltage, and the first verify voltage is less than or equal to the second threshold voltage.

It should be noted that the 3 σ criterion is also referred to as a Pauta criterion; it firstly assumes that a group of detection data only contains a random error, an operation of calculation and processing is performed on the detection data to obtain a standard deviation, an interval is determined according to a certain probability, and considers that an error exceeding the interval does not belong to a random error but is a gross error, and that data containing the error should be eliminated. The 3 σ criterion is based on the equal-precision repeated measurement of the normal distribution, such that it is difficult for the interference or noise of the singular data to meet the normal distribution. If an absolute value of a residual error of a measurement value in a group of measurement data is greater than vi>3 σ, the measurement value is a bad value and should be removed. Generally, the error equal to ±3 σ is used as a limit error, and for a random error of a normal distribution, the probability that the random error falls outside the range of ±3 σ is only 0.27%, which occurs with a small possibility in the limited number of measurements, so that a 3 σ criterion exists. In a Gaussian normal distribution, corresponding percentages that a random error is within one standard deviation +1 σ,-1 σ, two standard deviations +2 σ,-2 σ, three standard deviations +3 σ,-3 σ from the average value u (i.e., 0 σ) can be determined according to the 3 σ criterion.

For example, referring to FIG. 8, the threshold voltage distribution of the plurality of ferroelectric memory cells which are in the erased state in the target memory block (E) is a Gaussian normal distribution Φ1, wherein a threshold voltage located at 0 σ (that is, at an average value u) in the Gaussian normal distribution Φ1 is a first threshold voltage Vth1, a threshold voltage located at +3 σ is a second threshold voltage Vth2, and the value of the first verify voltage Vpv_ers1 is between the value of the first verify voltage Vth1 and the value of the second threshold voltage Vth2, that is, Vth1≤Vpv_ers1≤Vth2.

In some examples, the peripheral circuit is further configured to: in combination with a 3-sigma (3 σ) criterion, determine that the value of the first verify voltage includes one of corresponding threshold voltage values located at +1 σ, +1. 5 σ, +2 σ, +2. 5 σ, +3 σ in a Gaussian normal distribution. In other words, the value of the first verify voltage Vpv_ers1 may be the value of the corresponding threshold voltage located at +1 σ, or may be the value of the corresponding threshold voltage located at +1.5 σ, +2 σ, +2.5 σ, or +3 σ.

In some examples, the voltage value of the first verify voltage Vpv_ers1 ranges from 3V −5V. In some examples, the voltage value of the first verify voltage Vpv_ers1 may be taken from 3V, 3.25V, 3.5V, 4V, 4.5V or 5V.

Here, after a verify operation is performed, a program pulse (PGM pulse), i.e., the first program voltage Vpgm_ers1, is applied on the selected word line coupled to the target memory block to perform the first program operation. In some examples, the voltage value of the first program voltage Vpgm_ers1 ranges from 5V-15V. In some examples, the voltage value of the first program voltage may be taken from 5V, 6V, 7V, 8V, 9V, 10V, 11V, 12V, 13V, 14V, or 15V. It should be understood that the voltage value of the first program voltage Vpgm_ers1 is greater than the voltage value of the first verify voltage Vpv_ers1.

Here, after the first program operation is performed, a second verify voltage Vpv_ers2 is applied on the selected word line coupled to the target memory block to perform a second verify operation. The value of the second verify voltage Vpv_ers2 is the same as the value of the first verify voltage Vpv_ers1, i.e., Vpv_ers2=Vpv_ers1. That is, the voltage value of the second verify voltage Vpv_ers2 may be taken between the value of the first verify voltage Vth1 and the value of the second threshold voltage Vth2 in the Gaussian normal distribution, i.e., Vth1≤Vpv_ers2≤Vth2. In some other examples, the value of the voltage value of the second verify voltage Vpv_ers2 may be a value of a corresponding threshold voltage located at +1 σ in the Gaussian normal distribution Φ1, or may be a value of a corresponding threshold voltage located at +1.5 σ, +2 σ, +2.5 σ or +3 σ in the Gaussian normal distribution Φ1. In some examples, the voltage value of the second verify voltage Vpv_ers2 ranges from 3V-5V. In some examples, the voltage value of the second verify voltage Vpv_ers2 may be 3V, 3.25V, 3.5V, 4V, 4.5V or 5V.

In some examples, the peripheral circuit is further configured to: determine the threshold voltage distribution of the plurality of ferroelectric memory cells in the target memory block after the first program operation is performed, based on the second verify operation. In some examples, based on the second verify operation, the number of ferroelectric memory cells of which threshold voltages are greater than the first verify voltage in the plurality of ferroelectric memory cells in the target memory block after the first program operation is performed may be determined.

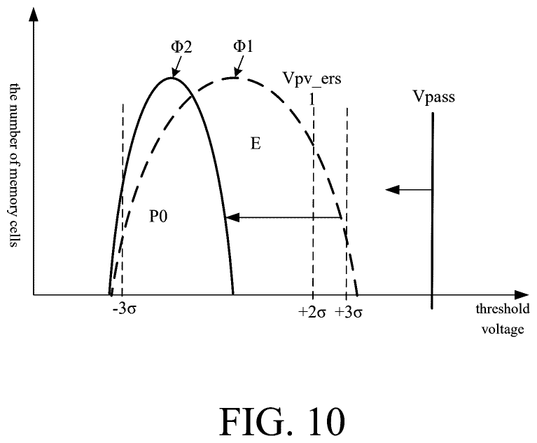

In practical application, referring to FIG. 10, after the first program operation is performed, the threshold voltage distribution of the plurality of ferroelectric memory cells in the target memory block is Gaussian normal distribution Φ2, and it can be seen from FIG. 10 that before the first program operation is performed, the width of the threshold voltage Gaussian normal distribution Φ1 of the plurality of ferroelectric memory cells in the target memory block is different from the width of the threshold voltage Gaussian normal distribution Φ2 of the plurality of ferroelectric memory cells in the target memory block after the first program operation is performed. Moreover, the width of the Gaussian normal distribution Φ2 of the threshold voltages of the plurality of ferroelectric memory cells after the first program operation is performed is less than the width of the Gaussian normal distribution Φ1 of the threshold voltages of the plurality of ferroelectric memory cells before the first program operation is performed. In other words, by performing the first program operation on the plurality of ferroelectric memory cells, the width of the threshold voltage distribution thereof can be reduced, thereby facilitating reducing the pass voltage applied on the unselected word lines in the read operation, further improving the problems caused by read disturbance, and improving the performance and reliability of the memory device and the system thereof. For example, the memory state corresponding to the Gaussian normal distribution Φ2 shown in FIG. 10 is the state P0.

In some examples, before the first verify operation is performed, the plurality of ferroelectric memory cells in the target memory block may be divided into a first group of memory cells and a second group of memory cells, wherein the threshold voltages of the first group of memory cells are less than or equal to the first verify voltage, and the threshold voltages of the second group of memory cells are greater than the first verify voltage; after the first verify operation, the first program operation, and the second verify operation are performed, the peripheral circuit may be further configured to: determine, based on the first verify operation, that the number of memory cells in the second group is a first number, that is, before the first program operation is performed, the number of memory cells of which threshold voltages are greater than the first verify voltage in the plurality of memory cells in the target memory block; and determine, based on the second verify operation, the number of memory cells in the second group to be a second number, that is, after the first program operation is performed, the number of memory cells of which threshold voltages are greater than the first verify voltage in the plurality of memory cells in the target memory block, wherein the second number is less than the first number.

In some examples, the peripheral circuit is further configured to: determine, based on a verify result of the second verify operation, whether to perform the second program operation; wherein the second program voltage for the second program operation is greater than or equal to the first program voltage.

It should be noted that after the first program operation is performed, in the plurality of ferroelectric memory cells in the second group of memory cells, a portion of the ferroelectric memory cells may be programmed to a target programmed state (for example, P1, P2, P3, P4, P5, P6, and P7 shown in FIG. 8), and another portion of ferroelectric memory cells are still in an erased state; it is also possible that all are programmed to the target programmed state; and it is also possible that all are in an erased state. Further, when a plurality of ferroelectric memory cells in the second group of memory cells are still in an erased state after the first program operation is performed, threshold voltages of the plurality of ferroelectric memory cells in the second group of memory cells may all be less than the first verify voltage; or it is also possible that a portion of the threshold voltages are less than the first verify voltage, and another portion of the threshold voltages are greater than the first verify voltage. However, it should be understood that after the first program operation is performed, the number of memory cells of which threshold voltages are greater than the first verify voltage in the second group of memory cells is reduced, so that the width of the threshold voltage distribution is reduced. In addition, it should be noted that the purpose of reducing the threshold voltage distribution can be achieved through one program operation, and in this case, the operation time can be saved, and the operation efficiency can be improved.

In some examples, the peripheral circuit is further configured to: determine to perform the second program operation when the verify result of the second verify operation indicates that the second number is greater than 0; and determine not to perform the second program operation when the verify result of the second verify operation indicates that the second number is equal to 0.

In some examples, referring to FIG. 10, an example in which the first verify voltage Vpv_ers is a corresponding threshold voltage value located at +2 σ is taken. Before the first program operation is performed, the verify result of the first verify operation indicates that the threshold voltages of the 10000-bit (the first number) of ferroelectric memory cells are greater than the corresponding voltage value located at 2 σ. After the first program operation is performed, the verify result of the second verify operation indicates that the threshold voltages of the 0 bit (the second number) of ferroelectric memory cells are greater than the corresponding voltage value located at 2 σ. At this time, the second number is equal to 0, that is, the second program operation will not be performed. In other words, after the first program operation is performed, the threshold voltages of the second group of memory cells are all less than the first verify voltage, that is, the threshold voltages of all the ferroelectric memory cells in the target memory block are all less than the first verify voltage.

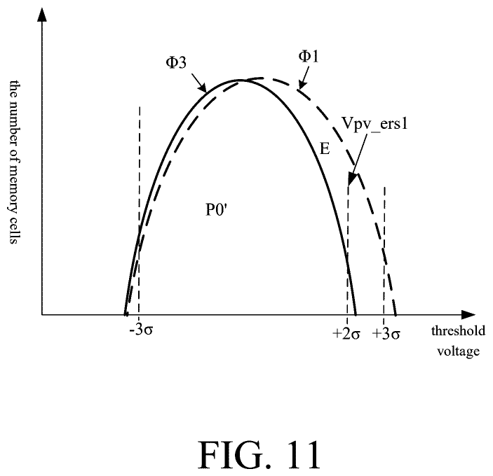

In some examples, referring to FIG. 11, an example in which the first verify voltage Vpv_ers is a corresponding threshold voltage value located at +2 σ is taken. Before the first program operation is performed, the verify result of the first verify operation indicates that the threshold voltages of the 10000-bit (the first number) of ferroelectric memory cells are greater than the corresponding voltage value located at 2 σ, the corresponding threshold voltage distribution refers to Gaussian normal distribution Φ1, and the corresponding memory state is the erased state E. After the first program operation is performed, the verify result of the second verify operation indicates that the threshold voltages of the remaining 5000 bit (the second number) of ferroelectric memory cells are greater than the corresponding voltage value located at 2 σ, the corresponding threshold voltage distribution refers to Gaussian normal distribution Φ3, and the corresponding memory state is state P0′. At this time, the second number is greater than 0, and the second program operation may continue to be performed.

In some examples, in the process of performing the second program operation, a program pulse, i.e., the second program voltage Vpgm_ers2, is applied on the selected word line coupled to the target memory block to perform the second program operation. In some examples, the voltage value of the second program voltage Vpgm_ers2 ranges from 5V-15V. Here, the voltage value of the second program voltage Vpgm_ers2 may be greater than or equal to the voltage value of the first program voltage Vpgm_ers1. In some examples, the second program voltage Vpgm_ers2 is greater than the first program voltage Vpgm_ers1 by 0.5V, that is, Vpgm_ers2=Vpgm_ers1+0.5.

In the examples of the disclosure, after the second program operation is performed, a third verify operation may still be performed to determine whether the threshold voltages of the plurality of ferroelectric memory cells in the target memory block are still greater than the first verify voltage after the second program operation is performed. Operate in this way until the verify result of the last verify operation indicates that the threshold voltages of all the ferroelectric memory cells in the target memory block are less than the first verify voltage.

It should be noted that, in some examples, after the second program operation is performed, in the plurality of ferroelectric memory cells in the second group of memory cells, a portion of ferroelectric memory cells may be programmed to the target programmed state, and another portion of ferroelectric memory cells may still be in the erased state, it is also possible that all are programmed to the target programmed state, and it is also possible that all are in an erased state.

However, it should be understood that after the second program operation is performed, when the second group of memory cells are programmed to the corresponding target programmed states, threshold voltages corresponding to a plurality of the target programmed states are all less than a minimum value of threshold voltages corresponding to the erased state. For example, referring to FIG. 8, the number of storage bits of the memory cell is 3 bits, the target programmed state is one programmed state of 8 memory states including an erased state (E) and 7 programmed states (P1, P2, P3, P4, P5, P6, and P7), and the second group of memory cells are programmed to at least one programmed state of the 7 programmed states (P1, P2, P3, P4, P5, P6, and P7), here, threshold voltages corresponding to the 7 programmed states (P1, P2, P3, P4, P5, P6, and P7) are all less than a minimum value of threshold voltages corresponding to the erased state (E).

It should be noted that the purpose of reducing the width of the threshold voltage distribution is achieved through multiple program operations, and in this case, the threshold voltage distribution can be narrowed more accurately, which facilitates improving the operation performance and reliability of the memory device.

In some examples, the target memory block includes M sub-memory blocks; a sub-memory block includes a plurality of ferroelectric memory cells; the selected word line is coupled to the M sub-memory blocks; the memory device includes M top select gates; the M sub-memory blocks are correspondingly coupled to the M top select gates; M is a positive integer; and the peripheral circuit is configured to cause that: when performing the first verify operation, the first program operation and the second verify operation on a target sub-memory block of the M sub-memory blocks, a top select gate coupled to the target sub-memory block is in an on state, and top select gates coupled to remaining sub-memory blocks of the M sub-memory blocks other than the target sub-memory block are all in an off state. Thus, corresponding operations may be only performed on the target sub-memory block, thereby improving operation efficiency and reducing interference to other sub-memory blocks, such as over-programming.

In some examples, the memory device further includes: a plurality of bit lines; wherein the first group of memory cells are coupled to a first bit line of the plurality of bit lines; the second group of memory cells are coupled to a second bit line of the plurality of bit lines; and the peripheral circuit is further configured to apply a first voltage on the first bit line and a second voltage on the second bit line in a process of performing the first program operation, the first voltage is greater than the second voltage. In some examples, the first voltage is Vdd, and the second voltage is Vss, such as 0V.

In some examples, referring to FIG. 10, the peripheral circuit is configured to: apply a pass voltage Vpass on unselected word lines of the plurality of word lines in a process of performing the first verify operation; wherein the pass voltage Vpass is greater than a maximum threshold voltage of the plurality of ferroelectric memory cells in the target memory block.

In some examples, the memory device includes a ferroelectric memory. In some examples, the memory device includes a three-dimensional NAND-type ferroelectric memory.

In the examples of the present disclosure, by reducing the width of the threshold voltage distribution of the ferroelectric memory cells which are in the erased state in the target memory block, the threshold voltages of the plurality of ferroelectric memory cells are more compact, which facilitates the reducing of the pass voltage applied on the unselected word lines in the read operation, further improving the problems caused by read interference, and improving the performance and reliability of the memory device and the system thereof.

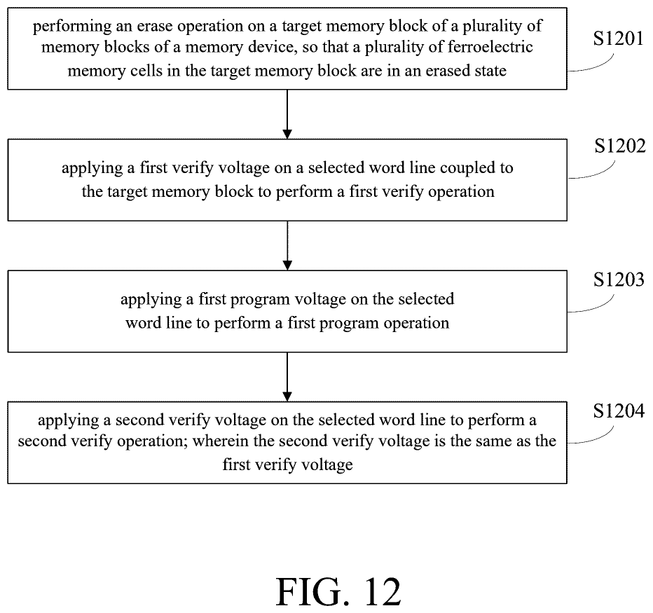

Based on the above memory device, the present disclosure further provides a method of operating the memory device, FIG. 12 is a schematic flowchart of the method of operating the memory device provided by an example of the present disclosure, and as shown in FIG. 12, the method of operating the memory device includes the following operations:

Operation S1201: performing an erase operation on a target memory block of a plurality of memory blocks of a memory device, so that a plurality of ferroelectric memory cells in the target memory block are in an erased state.

Operation S1202: applying a first verify voltage on a selected word line coupled to the target memory block to perform a first verify operation.

Operation S1203: applying a first program voltage on the selected word line to perform a first program operation.

Operation S1204: applying a second verify voltage on the selected word line to perform a second verify operation; wherein the second verify voltage is the same as the first verify voltage.

In some examples, the method further includes: determining, based on the first verify operation, the number of ferroelectric memory cells of which threshold voltages are greater than the first verify voltage in the plurality of ferroelectric memory cells in the target memory block before the first program operation is performed; and determining, based on the second verify operation, the number of ferroelectric memory cells of which threshold voltages are greater than the first verify voltage in the plurality of ferroelectric memory cells in the target memory block after the first program operation is performed.

In some examples, the plurality of ferroelectric memory cells in the target memory block include a first group of memory cells and a second group of memory cells, threshold voltages of the first group of memory cells are less than or equal to the first verify voltage, and threshold voltages of the second group of memory cells are greater than the first verify voltage; and the method further includes: determining, based on the first verify operation, the number of the first group of memory cells to be a first number; and determining, based on the second verify operation, the number of memory cells in the second group to be a second number, wherein the second number is less than the first number.

In some examples, the method further includes: determining whether to perform a second program operation based on a verify result of the second verify operation; and wherein a second program voltage for the second program operation is greater than or equal to the first program voltage.

In some examples, the method further includes: determining to perform the second program operation when the verify result of the second verify operation indicates that the second number is greater than 0; and determining not to perform the second program operation when the verify result of the second verify operation indicates that the second number is equal to 0.

In some examples, after the first program operation or the second program operation is performed, the second group of memory cells are programmed to corresponding target programmed states; and threshold voltages corresponding to a plurality of the target programmed states are all less than a minimum value of threshold voltages corresponding to the erased state.

In some examples, threshold voltages of the plurality of ferroelectric memory cells which are in the erased state in the target memory block are in a Gaussian normal distribution; and the method further includes: determining, in combination with a 3-sigma (3 σ) criterion, that a threshold voltage located at 0 σ in the Gaussian normal distribution is a first threshold voltage, and a threshold voltage located at +3 σ is a second threshold voltage; wherein the first threshold voltage is less than or equal to the first verify voltage, and the first verify voltage is less than or equal to the second threshold voltage.

In some examples, threshold voltages of the plurality of ferroelectric memory cells which are in the erased state in the target memory block are in a Gaussian normal distribution; and the method further includes: determining, in combination with a 3-sigma (3 σ) criterion, that a value of the first verify voltage includes one of corresponding threshold voltage values located at +1 σ, +1.5 σ, +2 σ, +2.5 σ, +3 σ in the Gaussian normal distribution.

In some examples, the method further includes: performing, after the erase operation is performed, an erase verify operation by obtaining a sensing current on the selected word line, wherein when the sensing current is less than a preset value, determine that the erase verify operation passes.

In some examples, the target memory block includes M sub-memory blocks; a sub-memory block includes a plurality of ferroelectric memory cells; the selected word line is coupled to the M sub-memory blocks; the memory device includes M top select gates; the M sub-memory blocks are correspondingly coupled to the M top select gates; M is a positive integer; and the method further includes: when performing the first verify operation, the first program operation, and the second verify operation on a target sub-memory block of the M sub-memory blocks, a top select gate coupled to the target sub-memory block is in an on state, and top select gates coupled to remaining sub-memory blocks of the M sub-memory blocks other than the target sub-memory block are all in an off state.

In some examples, the memory device further includes: a plurality of bit lines; the first group of memory cells are coupled to a first bit line of the plurality of bit lines; the second group of memory cells are coupled to a second bit line of the plurality of bit lines; and the method further includes: applying a first voltage on the first bit line and a second voltage on the second bit line in a process of performing the first program operation, wherein the first voltage is greater than the second voltage.

In some examples, the memory device further includes a plurality of word lines; and the method further includes: applying a pass voltage on unselected word lines of the plurality of word lines in a process of performing the first verify operation, wherein the pass voltage is greater than a maximum threshold voltage of the plurality of ferroelectric memory cells in the target memory block.

In some examples, a voltage value of the first verify voltage ranges from 3V-5V.

In some examples, a voltage value of the first program voltage ranges from 5V-15V.

The operating method mentioned in the foregoing examples has been described in detail in the foregoing examples related to the memory device, and will not be repeated for brevity.

An example of the present disclosure further provide a memory system, and the memory system includes: at least one memory device as described in the foregoing examples; and a memory controller coupled to the memory device.

The memory controller described herein may be the memory controller shown in FIG. 1, FIG. 2, FIG. 3 and FIG. 9, and the memory device described herein may be the memory device shown in FIG. 1 to FIG. 4 and FIG. 9. Other details related to the memory controller and the memory device have been described in detail above, and the structure and composition of the memory system may refer to the detailed descriptions of FIG. 1, FIG. 2, FIG. 3 and FIG. 9, and will not be repeated for brevity.

Based on the foregoing method of operating the memory device, an example of the present disclosure further provides a non-transitory computer-readable storage medium having stored thereon a computer program that, when performed by a memory system, implement the method of operating the memory device in any one of the foregoing examples.

Herein, all or part of the processes of the operating method in the foregoing examples may be implemented by instructing a related hardware by using a computer program, the program may be stored in a computer-readable storage medium, and when the program is performed, the processes of the examples of the foregoing methods may be included. The non-transitory computer-readable storage medium may be a ferromagnetic random access memory (FRAM), a read-only memory (ROM), a programmable read-only memory (PROM), an erasable programmable read-only memory (EPROM), an electrically erasable programmable read-only memory (EEPROM), a flash memory, a magnetic surface memory, a compact disc or a compact disc read-only memory (CD-ROM), or the like; or may be various devices including one of the foregoing memory devices or any combination thereof.

The features disclosed in the several device examples provided by the present disclosure may be arbitrarily combined without conflict to obtain a new device example.

The methods disclosed in the several method examples provided by the present disclosure may be arbitrarily combined without conflict to obtain new method examples.

Some disclosed examples provide a memory device, an operating method thereof and a memory system.

In a first aspect, an example of the present disclosure provides a memory array, the memory array includes: a plurality of memory blocks, a memory block includes a plurality of ferroelectric memory cells; a plurality of word lines coupled to the memory array; and a peripheral circuit coupled to the memory array and configured to: perform an erase operation on a target memory block of the plurality of memory blocks so that a plurality of ferroelectric memory cells in the target memory block are in an erased state; apply a first verify voltage on a selected word line coupled to the target memory block to perform a first verify operation; apply a first program voltage on the selected word line to perform a first program operation; and apply a second verify voltage on the selected word line to perform a second verify operation; wherein the second verify voltage is the same as the first verify voltage.

In some examples, the peripheral circuit is further configured to: determine, based on the first verify operation, the number of ferroelectric memory cells of which threshold voltages are greater than the first verify voltage in the plurality of ferroelectric memory cells in the target memory block before the first program operation is performed; and determine, based on the second verify operation, the number of ferroelectric memory cells of which threshold voltages are greater than the first verify voltage in the plurality of ferroelectric memory cells in the target memory block after the first program operation is performed.

In some examples, the plurality of ferroelectric memory cells in the target memory block include a first group of memory cells and a second group of memory cells, threshold voltages of the first group of memory cells are less than or equal to the first verify voltage, and threshold voltages of the second group of memory cells are greater than the first verify voltage; and the peripheral circuit is further configured to: determine, based on the first verify operation, the number of memory cells in the second group to be a first number; and determine, based on the second verify operation, the number of memory cells in the second group to be a second number, wherein the second number is less than the first number.

In some examples, the peripheral circuit is further configured to: determine whether to perform a second program operation based on a verify result of the second verify operation; wherein a second program voltage for the second program operation is greater than or equal to the first program voltage.

In some examples, the peripheral circuit is further configured to: determine to perform the second program operation when the verify result of the second verify operation indicates that the second number is greater than 0; and determine not to perform the second program operation when the verify result of the second verify operation indicates that the second number is equal to 0.

In some examples, after the first program operation or the second program operation is performed, the second group of memory cells are programmed to corresponding target programmed states; and threshold voltages corresponding to a plurality of the target programmed states are all less than a minimum value of threshold voltages corresponding to the erased state.

In some examples, threshold voltages of the plurality of ferroelectric memory cells which are in the erased state in the target memory block are in a Gaussian normal distribution; and the peripheral circuit is further configured to: determine, in combination with a 3-sigma (3 σ) criterion, that a threshold voltage located at 0 σ in the Gaussian normal distribution is a first threshold voltage, and a threshold voltage located at +3 σ is a second threshold voltage; wherein the first threshold voltage is less than or equal to the first verify voltage, and the first verify voltage is less than or equal to the second threshold voltage.

In some examples, threshold voltages of the plurality of ferroelectric memory cells which are in the erased state in the target memory block are in a Gaussian normal distribution; and the peripheral circuit is further configured to: determine, in combination with a 3-sigma (3 σ) criterion, that a value of the first verify voltage includes one of corresponding threshold voltage values located at +1 σ, +1.5 σ, +2 σ, +2.5 σ, +3 σ in the Gaussian normal distribution.

In some examples, the peripheral circuit is further configured to: perform an erase verify operation by obtaining a sensing current on the selected word line after the erase operation is performed; wherein when the sensing current is less than a preset value, determine that the erase verify operation passes.

In some examples, the target memory block includes M sub-memory blocks; a sub-memory block includes a plurality of ferroelectric memory cells; the selected word line is coupled to the M sub-memory blocks; the memory device includes M top select gates; the M sub-memory blocks are correspondingly coupled to the M top select gates; M is a positive integer; and the peripheral circuit is configured to cause that: when performing the first verify operation, the first program operation, and the second verify operation on a target sub-memory block of the M sub-memory blocks, a top select gate coupled to the target sub-memory block is in an on state, and top select gates coupled to remaining sub-memory blocks of the M sub-memory blocks other than the target sub-memory block are all in an off state.

In some examples, the memory device further includes a plurality of bit lines; wherein the first group of memory cells are coupled to a first bit line of the plurality of bit lines; the second group of memory cells are coupled to a second bit line of the plurality of bit lines; and the peripheral circuit is further configured to apply a first voltage on the first bit line and a second voltage on the second bit line in a process of performing the first program operation, the first voltage is greater than the second voltage.

In some examples, the peripheral circuit is configured to: apply a pass voltage on unselected word lines of the plurality of word lines in a process of performing the first verify operation, wherein the pass voltage is greater than a maximum threshold voltage of the plurality of ferroelectric memory cells in the target memory block.

In some examples, a voltage value of the first verify voltage ranges from 3V-5V.

In some examples, a voltage value of the first program voltage ranges from 5V-15V.

In a second aspect, an example of the present disclosure provides a memory system. The memory system includes: at least one memory device of the above examples of the present disclosure; and a memory controller coupled to the memory device and controlling the memory device.

In a third aspect, an example of the present disclosure provides a method for operating a memory device. The method includes: performing an erase operation on a target memory block of a plurality of memory blocks of the memory device so that a plurality of ferroelectric memory cells in the target memory block are in an erased state; applying a first verify voltage on a selected word line coupled to the target memory block to perform a first verify operation; applying a first program voltage on the selected word line to perform a first program operation; and applying a second verify voltage on the selected word line to perform a second verify operation, wherein the second verify voltage is the same as the first verify voltage.

In some examples, the method further includes: determining, based on the first verify operation, the number of ferroelectric memory cells of which threshold voltages are greater than the first verify voltage in the plurality of ferroelectric memory cells in the target memory block before the first program operation is performed; and determining, based on the second verify operation, the number of ferroelectric memory cells of which threshold voltages are greater than the first verify voltage in the plurality of ferroelectric memory cells in the target memory block after the first program operation is performed.

In some examples, the plurality of ferroelectric memory cells in the target memory block include a first group of memory cells and a second group of memory cells, threshold voltages of the first group of memory cells are less than or equal to the first verify voltage, and threshold voltages of the second group of memory cells are greater than the first verify voltage; and the method further includes: determining, based on the first verify operation, the number of memory cells in the second group to be a first number; and determining, based on the second verify operation, the number of memory cells in the second group to be a second number, wherein the second number is less than the first number.

In some examples, the method further includes: determining whether to perform a second program operation based on a verify result of the second verify operation; and wherein a second program voltage for the second program operation is greater than or equal to the first program voltage.

In some examples, the method further includes: determining to perform the second program operation when the verify result of the second verify operation indicates that the second number is greater than 0; and determining not to perform the second program operation when the verify result of the second verify operation indicates that the second number is equal to 0.

In some examples, after the first program operation or the second program operation is performed, the second group of memory cells are programmed to corresponding target programmed states; and threshold voltages corresponding to a plurality of the target programmed states are all less than a minimum value of threshold voltages corresponding to the erased state.

In some examples, threshold voltages of the plurality of ferroelectric memory cells which are in the erased state in the target memory block are in a Gaussian normal distribution; and the method further includes: determining, in combination with a 3-sigma (3 σ) criterion, that a threshold voltage located at 0 σ in the Gaussian normal distribution is a first threshold voltage, and a threshold voltage located at +3 σ is a second threshold voltage; wherein the first threshold voltage is less than or equal to the first verify voltage, and the first verify voltage is less than or equal to the second threshold voltage.

In some examples, threshold voltages of the plurality of ferroelectric memory cells which are in the erased state in the target memory block are in a Gaussian normal distribution; and the method further includes: determining, in combination with a 3-sigma (3 σ) criterion, that a value of the first verify voltage includes one of corresponding threshold voltage values located at +1 σ, +1.5 σ, +2 σ, +2.5 σ, +3 σ in the Gaussian normal distribution.

In some examples, the method further includes: performing, after the erase operation is performed, an erase verify operation by obtaining a sensing current on the selected word line, wherein when the sensing current is less than a preset value, determine that the erase verify operation passes.

In some examples, the target memory block includes M sub-memory blocks; a sub-memory block includes a plurality of ferroelectric memory cells; the selected word line is coupled to the M sub-memory blocks; the memory device includes M top select gates; the M sub-memory blocks are correspondingly coupled to the M top select gates; M is a positive integer; and the method further includes: when performing the first verify operation, the first program operation, and the second verify operation on a target sub-memory block of the M sub-memory blocks, a top select gate coupled to the target sub-memory block is in an on state, and top select gates coupled to remaining sub-memory blocks of the M sub-memory blocks other than the target sub-memory block are all in an off state.

In some examples, the memory device further includes: a plurality of bit lines; wherein the first group of memory cells are coupled to a first bit line of the plurality of bit lines; the second group of memory cells are coupled to a second bit line of the plurality of bit lines; and the method further includes: applying a first voltage on the first bit line and a second voltage on the second bit line in a process of performing the first program operation, the first voltage is greater than the second voltage.

In some examples, the memory device further includes a plurality of word lines; and the method further includes:
applying a pass voltage on unselected word lines of the plurality of word lines in a process of performing the first verify operation, wherein the pass voltage is greater than a maximum threshold voltage of the plurality of ferroelectric memory cells in the target memory block.

In some examples, a voltage value of the first verify voltage ranges from 3V-5V.

In some examples, a voltage value of the first program voltage ranges from 5V-15V.

In the examples of the present disclosure, the first verify operation, the first program operation and the second verify operation are sequentially applied to the target memory block after an erase operation, and the first verify voltage and the second verify voltage are made to be the same, so that the threshold voltage distribution of the plurality of ferroelectric memory cells in the target memory block after the erase operation is performed is determined through the first verify operation, and the threshold voltage distribution of the plurality of ferroelectric memory cells in the target memory block after the first program operation is performed is determined through the second verify operation. Thus, a narrower threshold voltage distribution of the plurality of ferroelectric memory cells in the target memory block may be obtained by applying a program operation, which facilitates the reducing of the pass voltage applied on the unselected word line in a read operation, further improving the problems caused by read disturbance, and improving the performance and reliability of the memory device and the system thereof.

The above description is merely examples of the present disclosure, but the protection scope of the present disclosure is not limited thereto, and any person skilled in the art may easily conceive of changes or substitutions within the technical scope of the present disclosure, which shall be covered within the protection scope of the present disclosure.

What is claimed is:

1. A memory device comprising:
a memory array including a plurality of memory blocks, wherein a target memory block of the plurality of memory blocks includes a plurality of ferroelectric memory cells;
a plurality of word lines coupled to the memory array; and
a peripheral circuit coupled to the memory array and configured to:
perform an erase operation on the target memory block of the plurality of memory blocks to cause the plurality of ferroelectric memory cells in the target memory block to be in an erased state;
apply a first verify voltage on a selected word line coupled to the target memory block to perform a first verify operation;
apply a first program voltage on the selected word line to perform a first program operation; and
apply a second verify voltage on the selected word line to perform a second verify operation, wherein the second verify voltage is the same as the first verify voltage.

2. The memory device of claim 1, wherein the peripheral circuit is further configured to:
determine, based on the first verify operation, a first number of ferroelectric memory cells of which threshold voltages are greater than the first verify voltage in the plurality of ferroelectric memory cells in the target memory block before the first program operation is performed; and
determine, based on the second verify operation, a second number of ferroelectric memory cells of which threshold voltages are greater than the first verify voltage in the plurality of ferroelectric memory cells in the target memory block after the first program operation is performed.

3. The memory device of claim 2, wherein the plurality of ferroelectric memory cells in the target memory block include a first group of memory cells and a second group of memory cells, threshold voltages of the first group of memory cells are less than or equal to the first verify voltage, and threshold voltages of the second group of memory cells are greater than the first verify voltage; and the second number is less than the first number.

4. The memory device of claim 3, wherein the peripheral circuit is further configured to:
determine, based on a verify result of the second verify operation, whether to perform a second program operation;
wherein a second program voltage for the second program operation is greater than or equal to the first program voltage.

5. The memory device of claim 4, wherein the peripheral circuit is further configured to:
determine to perform the second program operation when the verify result of the second verify operation indicates that the second number is greater than 0; and
determine not to perform the second program operation when the verify result of the second verify operation indicates that the second number is equal to 0.

6. The memory device of claim 5, wherein:
after the first program operation or the second program operation is performed, the second group of memory cells are programmed to corresponding target programmed states;
and threshold voltages corresponding to a plurality of the target programmed states are all less than a minimum value of threshold voltages corresponding to the erased state.

7. The memory device of claim 1, wherein threshold voltages of the plurality of ferroelectric memory cells which are in the erased state in the target memory block are in a Gaussian normal distribution; and the peripheral circuit is further configured to:
determine, in combination with a 3-sigma (3 σ) criterion, that a threshold voltage located at 0 σ in the Gaussian normal distribution is a first threshold voltage, and a threshold voltage located at +3 σ is a second threshold voltage; wherein the first threshold voltage is less than or equal to the first verify voltage, and the first verify voltage is less than or equal to the second threshold voltage.

8. The memory device of claim 1, wherein threshold voltages of the plurality of ferroelectric memory cells which are in the erased state in the target memory block are in a Gaussian normal distribution; and the peripheral circuit is further configured to:
determine, in combination with a 3-sigma (3 σ) criterion, that a value of the first verify voltage includes one of corresponding threshold voltage values located at +1 σ, +1.5 σ, +2 σ,+2.5 σ, +3 σ in the Gaussian normal distribution.

9. The memory device of claim 1, wherein the peripheral circuit is further configured to:
perform, after the erase operation is performed, an erase verify operation by obtaining a sensing current on the selected word line, wherein when the sensing current is less than a preset value, determine that the erase verify operation passes.

10. The memory device of claim 3, wherein the target memory block includes M sub-memory blocks, one of the sub-memory block includes a plurality of the ferroelectric memory cells; the selected word line is coupled to the M sub-memory blocks; the memory device includes M top select gates; the M sub-memory blocks are correspondingly coupled to the M top select gates; M is a positive integer; and the peripheral circuit is configured to cause that:
when performing the first verify operation, the first program operation, and the second verify operation on a target sub-memory block of the M sub-memory blocks, a top select gate coupled to the target sub-memory block is in an on state, and top select gates coupled to remaining sub-memory blocks of the M sub-memory blocks other than the target sub-memory block are all in an off state.

11. The memory device of claim 10, further including: a plurality of bit lines; wherein the first group of memory cells are coupled to a first bit line of the plurality of bit lines; the second group of memory cells are coupled to a second bit line of the plurality of bit lines; and the peripheral circuit further configured to:
apply a first voltage on the first bit line and a second voltage on the second bit line in a process of performing the first program operation, wherein the first voltage is greater than the second voltage.

12. The memory device of claim 1, wherein the peripheral circuit is configured to:
apply a pass voltage on unselected word lines of the plurality of word lines in a process of performing the first verify operation, wherein the pass voltage is greater than a maximum threshold voltage of the plurality of ferroelectric memory cells in the target memory block.

13. The memory device of claim 1, wherein a voltage value of the first verify voltage ranges from 3V-5V.

14. The memory device of claim 1, wherein a voltage value of the first program voltage ranges from 5V-15V.

15. A memory system comprising:
at least one memory device, including:
a memory array including a plurality of memory blocks, wherein a target memory block of the plurality of memory blocks includes a plurality of ferroelectric memory cells;
a plurality of word lines coupled to the memory array; and
a peripheral circuit coupled to the memory array and configured to:
perform an erase operation on the target memory block of the plurality of memory blocks to cause the plurality of ferroelectric memory cells in the target memory block to be in an erased state;
apply a first verify voltage on a selected word line coupled to the target memory block to perform a first verify operation;
apply a first program voltage on the selected word line to perform a first program operation; and
apply a second verify voltage on the selected word line to perform a second verify operation, wherein the second verify voltage is the same as the first verify voltage; and
a memory controller coupled with the memory device and controlling the memory device.

16. A method of operating a memory device, the method comprising:
performing an erase operation on a target memory block of a plurality of memory blocks of the memory device to cause a plurality of ferroelectric memory cells in the target memory block to be in an erased state;
applying a first verify voltage on a selected word line coupled to the target memory block to perform a first verify operation;
applying a first program voltage on the selected word line to perform a first program operation; and
applying a second verify voltage on the selected word line to perform a second verify operation; wherein the second verify voltage is the same as the first verify voltage.

17. The method of claim 16, further including:
determining, based on the first verify operation, a first number of ferroelectric memory cells of which threshold voltages are greater than the first verify voltage in the plurality of ferroelectric memory cells in the target memory block before the first program operation is performed; and
determining, based on the second verify operation, a second number of ferroelectric memory cells of which threshold voltages are greater than the first verify voltage in the plurality of ferroelectric memory cells in the target memory block after the first program operation is performed.

18. The method of claim 17, wherein the plurality of ferroelectric memory cells in the target memory block include a first group of memory cells and a second group of memory cells, threshold voltages of the first group of memory cells are less than or equal to the first verify voltage, and threshold voltages of the second group of memory cells are greater than the first verify voltage; and the second number is less than the first number.

19. The method of claim 18, further including:
determining, based on a verify result of the second verify operation, whether to perform a second program operation;
wherein a second program voltage for the second program operation is greater than or equal to the first program voltage.

20. The method of claim 19, further including:
determining to perform the second program operation when the verify result of the second verify operation indicates that the second number is greater than 0; and
determining not to perform the second program operation when the verify result of the second verify operation indicates that the second number is equal to 0.
